(19) United States
(12) Patent Application Publication
(10) Pub. No.: US 2002/0107653 A1
(43) Pub. Date: Aug. 8, 2002

(54) Sharing data files in a test environment

(76) Inventor: Mark J. Kraffert, Meridian, ID (US)

Correspondence Address: Dan C. Hu, TROP, PRUNER & HU, P.C., Suite 100, 8554 Katy Freeway, Houston, TX, 77024, US

(21) Appl. No.: 09/776,364

(22) Filed: Feb. 2, 2001

(51) Int. Cl. G06F 19/00; G01R 27/28; G01R 31/00; G01R 31/14

(52) U.S. Cl. 702/119

(57) ABSTRACT

A test system having a test module for performing a test of one of plural databases. The test is performed using a common file. The file name of the common file is identified with a data source routine, which identifies the file name based on received first and second values. The first value is a predetermined string that is part of the file name of the common file, and the second value represents one of the plural databases. The file name of the common file is generated based on the concatenation of the first and second values.

### TECHNICAL FIELD

The invention relates to sharing data files in a test environment.

### BACKGROUND

Information technology has become an integral part of many businesses. For example, for vendors of goods or services, information technology software applications can track customer orders, from the point of order through manufacturing to shipping. Many applications are generally mission-critical in the sense that inadequate performance or failure of such applications may adversely impact a business. Software applications are becoming increasingly sophisticated and complex, and thus become more prone to failure if not tested properly.

In a typical test environment, there may be several functional areas where tests are performed. For example, a manufacturing company may have the following functional areas: order entry, factory planning, manufacturing, shipping, and invoice/accounting. In performing tests in each of the functional areas, it may sometimes be desirable to use the same data files. In many instances, the data files from one test may have to be physically copied to a location that is accessible by a test system in the next test. This is generally inefficient and is often associated with errors, since a wrong file may be copied.

### SUMMARY

In general, according to one embodiment, a method of performing a test comprises performing a first test with a first test system and performing a second test with a second test system. In each of the first and second test systems, plural parameters are received and a file name of a data file to use in each of the first and second tests is identified based on the plural parameters.

In general, according to another embodiment, a method of performing a test comprises receiving a first value and receiving a second value representing a database to perform a test on. The first value and the second value are combined to generate a file name referring to a test file.

Other or alternative features will become apparent from the following description, from the drawings, and from the claims.

### BRIEF DESCRIPTION OF THE DRAWINGS

FIG. 1 is a block diagram of an embodiment of a test environment.

FIG. 2 is a block diagram of a test system, a database system, and a server in the test environment of FIG. 1.

FIG. 3 illustrates the sharing of common data files by test systems in different functional areas.

FIG. 4 is a flow diagram of a process performed by a data source routine executable in the test system of FIG. 2.

### DETAILED DESCRIPTION

In the following description, numerous details are set forth to provide an understanding of the present invention. However, it will be understood by those skilled in the art that the present invention may be practiced without these details and that numerous variations or modifications from the described embodiments may be possible.

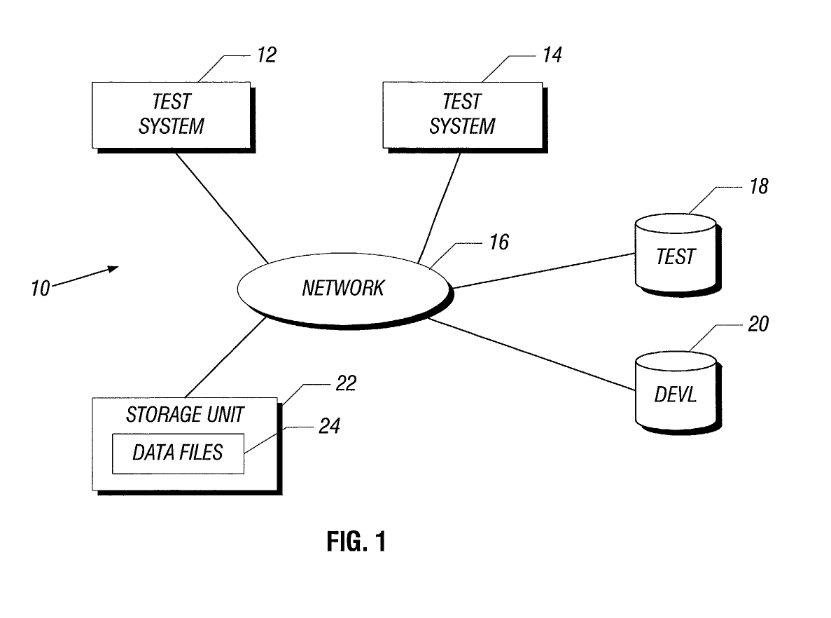

Referring to FIG. 1, a test environment 10 includes a network 16, such as a local area network (LAN) or a wide area network (WAN). The network 16 is coupled to a plurality of test systems 12, 14. Although only two test systems are illustrated, more than two can be used in further examples.

As further illustrated in FIG. 1, two databases 18 and 20 are also coupled to the network 16. A first database 18 is a TEST database, while a second database 20 is a DEVL or development database. An operator at one of the test systems 12, 14 can select one of the databases 18, 20 to perform a test on. The designation of TEST and DEVL for the databases is provided by way of example only, as further embodiments may employ other types of databases.

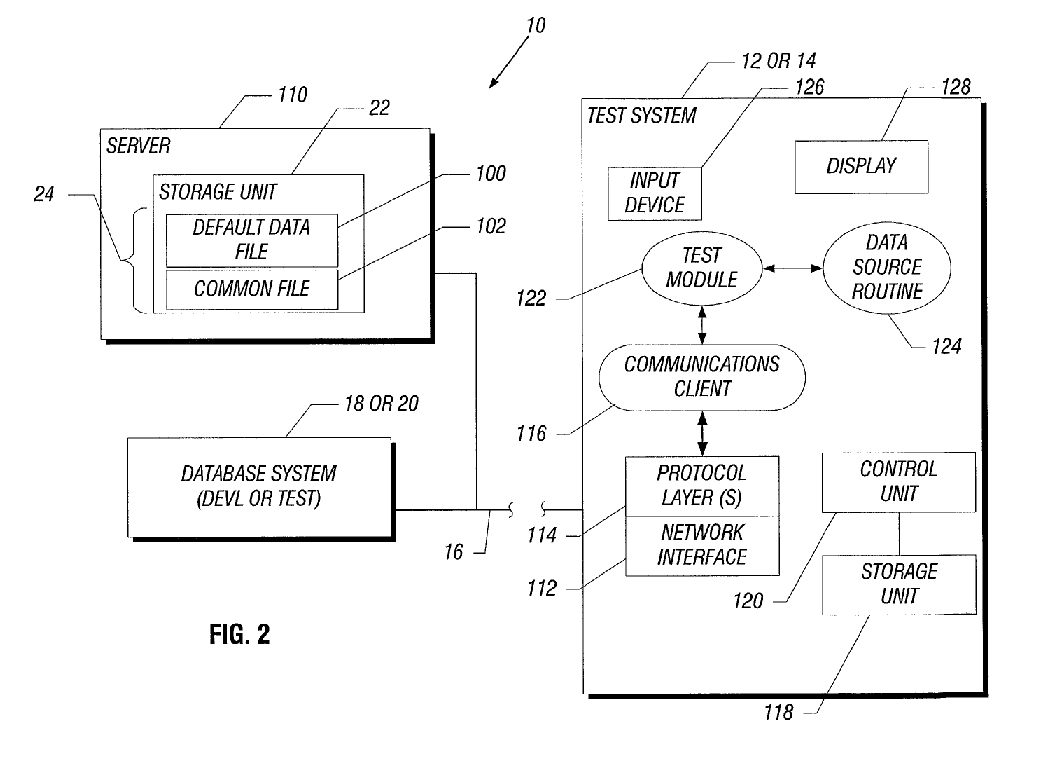

For a test performed by each test system 12, 14, one or more data files are used. The data files contain data that are used for performing data-driven tests on the database 18 or 20. In accordance with some embodiments, a common set of data files 24 are shared by the different tests systems 12, 14. Thus, for example, the test system 12 can use the data files 24 in a first test, and the test system 14 can use the same set of data files in the next test. In accordance with some embodiments, each of the test systems 12, 14 includes a data source routine 124 (FIG. 2) that provides a convenient mechanism for the different test systems 12, 14 to share the same data files 24. By using the data source routine 124, manual manipulation of the test systems 12, 14 to use the same data files 24 can be avoided. By receiving certain parameters, a data source routine 124 is able to identify the name of a data file to use. If in each test system the same parameter values are received, then the data source routine 124 will provide the same file name for identifying the data file to use in each test.

Referring to FIG. 2, components of the test system 12 or 14 are illustrated. The test system 12 or 14 includes a test module 122 that is able to perform tests of the database system 18 or 20 over the network 16. In one example embodiment, the test module 122 is the WINRUNNER testing tool from Mercury Interactive Corporation. In other embodiments, other types of testing tools can be used in the test system 12 or 14.

In performing tests, the test module 122 establishes a communications session with the database system 18 or 20 over the network 16. The communication session is established between a communications client 116 in the test system 12 or 14 and a communication server (not shown) in the database system 18 or 20. In one embodiment, the communications session is a Telnet session, which involves terminal emulation over a network. In terminal emulation, a client (the test system 12 or 14) behaves as though it is a terminal of another computer (the host), which in the example of FIG. 2 is the database system 18 or 20. Thus, in this example, the communications client 116 is a Telnet client. Once a Telnet session is established, the test system 12 or 14 is able to access files and software in the database system 18 or 20. In other embodiments, other types of communications sessions are possible over the network 16 between the test system 12 or 14 and the database system 18 or 20.

The test system 12 or 14 also includes a network interface 112 coupled to the network 16. One or more protocol layers 114 are provided above the network interface 112. For example, the protocol layers 14 may include an Ethernet layer and an Internet Protocol (IP) layer.

Also, as mentioned above, the test system 12 or 14 includes the data source routine 124 that enables the identification of a common set of data files 24 that can be shared by multiple test systems. The data source routine 124 can be invoked by the test module 122 for identifying the name of one of the data files 24. Although shown as separate components, the test module 122 and data source routine 124 may be part of the same integrated software module. For example, the data source routine can be a subroutine, function, or object that can be invoked within the test module 122.

Further, the test system 12 or 14 includes an input device 126 (e.g., a mouse and/or keyboard) through which a user can input data or commands. The test system 12 or 14 also includes a display 128 through which test results can be viewed.

The various software routines, including the test module 122, data source routine 124, and communications client 116 are executable on a control unit 120 in the test system 12 or 14. The control unit 120 is coupled to a storage unit 118 for storing data and instructions.

The data source routine 124 is capable of identifying file name of a default data file 100 or a common file 102 stored in the storage unit 22. There may be plural common files, with one file for each of the TEST and DEVL database system 18 or 20. The default data file 100 and common files 102 make up the common set of data files. As shown in FIG. 2, the storage unit 22 may be located in a server 110 (e.g., a network server or some other system accessible over the network 16).

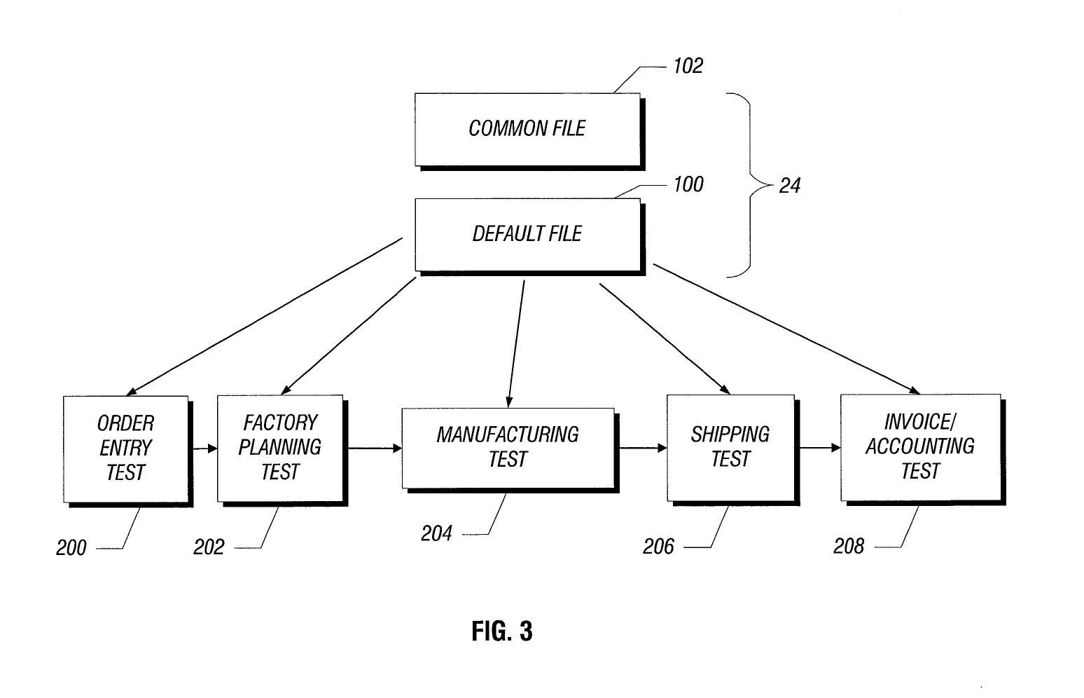

Referring to FIG. 3, in accordance with one example, the common set of data files 24 are shared by test systems 200, 202, 204, 206, and 208 in different functional areas. For example, the test system 200 is used to test an order entry area, the test system 202 is used to test a factory planning area, the test system 204 is used to test a manufacturing area, the test system 206 is used to test a shipping area, and a test system 208 is used to test an invoice/accounting area. The data source routine 124 executable in each of the test systems 200, 202, 204, 206, and 208 will automatically identify the correct data file to use without manual configuration of each test system or the creation of different custom scripts in each test system to find the correct file name. In some embodiments, all that needs to occur is the provision of predetermined parameters to the data source routine 124 (either by the test module 122 or by the user) to enable the identification of the file name of the common data file.

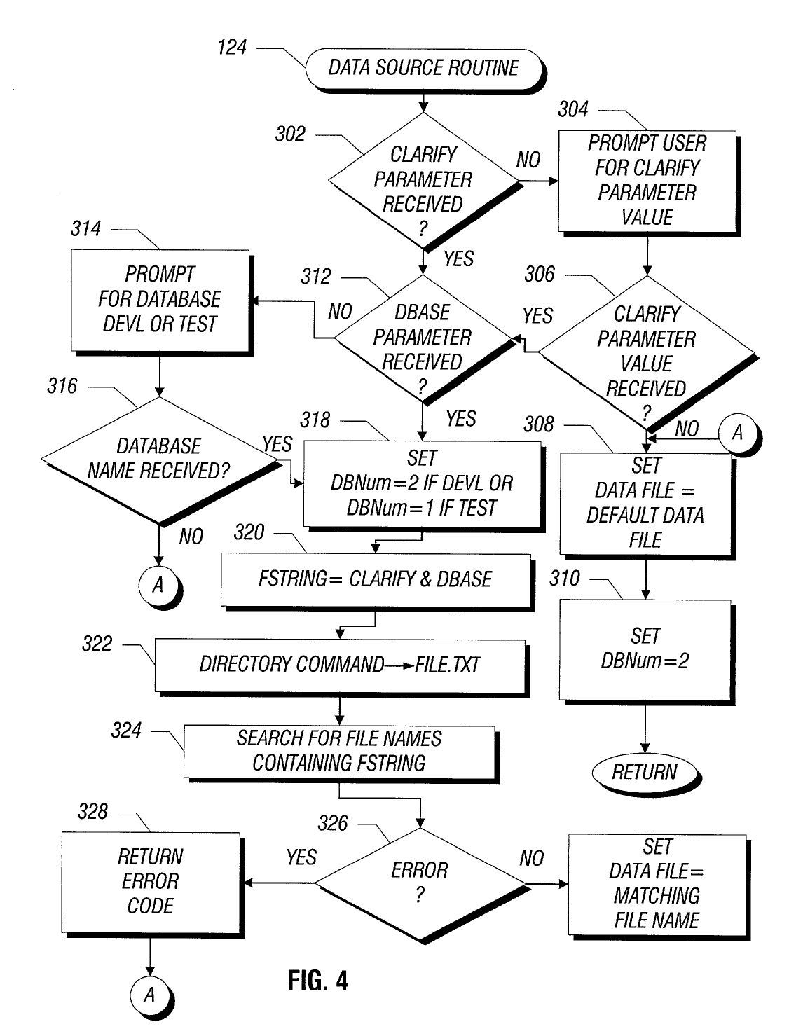

Referring to FIG. 4, a process according to one embodiment performed by the data source routine 124 is illustrated. The data source routine 124 is called by the test module 122. In the call, the test module 122 can set a Clarify parameter and a DBase parameter. The Clarify parameter can have a predefined common value, with the Clarify parameter value being part of the file name of a common file 102. The DBase parameter specifies the database to be tested, either the TEST database 18 or the DEVL database 20.

The data source routine 124 determines (at 302) whether a Clarify parameter was received in the call from the test module 122. If not, the data source routine 124 then prompts (at 304) the user for a Clarify parameter value. Next, the data source routine 124 determines if the user has entered a Clarify parameter value (at 306). The user is given a predetermined period of time to enter the Clarify parameter value. If a Clarify parameter value was not received, then the data source routine 124 sets a parameter DataFile equal to DefaultDataFile (at 308). The value DefaultDataFile refers to the default data file 100 (FIG. 2). Next, the data source routine 124 sets (at 310) a parameter DBNum to the value 2, which corresponds to the DEVL database 20. Thus, if the Clarify parameter is not received, then the default data file 100 is used and the DEVL database 20 is tested.

If the data source routine 124 determines (at 302 or 306) that the Clarify parameter has been received, then the data source routine 124 next determines if the DBase parameter is received (at 312). If not, the data source routine 124 prompts the user (at 314) for the DBase value (either DEVL or TEST). The data source routine 124 waits (at 316) for entry of the database name by the user. If a database name is not entered after a predetermined time period, the parameter DataFile is set to the DefaultDataFile value and DBNum is set to the value 2 (at 308 and 310).

If the database name has been received (at 312 or 316), then the value of DBNum is set to the appropriate value (1 for TEST or 2 for DEVL). Next, a parameter FString is set (at 320) to the concatenation of the Clarify and DBase parameters, that is,

FString=Clarify, DBase.

The data source routine 124 then performs (at 322) a directory list command on the server 110 in which the common set of data files 24 are kept. The output of the directory command is routed to a file FILE.TXT. The file FILE.TXT is then opened and a search is performed to find file names that contain the string FString.

Next, it is determined if an error occurred (at 326). An error may occur if a match is not found or if there are more than one file name containing the string FString. If an error is determined, then an error code is returned (at 328) and the DataFile and DBNum parameters are set at 308 and 310.

However, if an error did not occur (at 326), then the parameter DataFile is set to the matching file name. This is the file that is then used as the data file for the test to be performed by the test module 122.

The various software routines or modules, including the test module 122 and data source routine 124, are executable on corresponding one or more control units in each test system. Each of the control units includes a microprocessor, a microcontroller, a processor card (including one or more microprocessors or microcontrollers), or other control or computing devices. As used here, a “controller” refers to hardware, software, or a combination of both. A “controller” can refer to a single component or to plural components (whether software or hardware).

The storage units or devices referred to herein include one or more machine-readable storage media for storing data and instructions. The storage media include different forms of memory including semiconductor memory devices such as dynamic or static random access memories (DRAMs or SRAMs), erasable and programmable read-only memories (EPROMs), electrically erasable and programmable read-only memories (EEPROMs) and flash memories; magnetic disks such as fixed, floppy and removable disks; other magnetic media including tape; and optical media such as compact disks (CDs) or digital video or versatile disks (DVDs). Instructions that make up the various software routines or modules are stored in respective storage units. The instructions when executed by a respective control unit cause the corresponding system to perform programmed acts.

The instructions of the software routines or modules are loaded or transported to each system in one of many different ways. For example, code segments including instructions stored on floppy disks, CD or DVD media, a hard disk, or transported through a network interface card, modem, or other interface device are loaded into the system and executed as corresponding software routines or modules. In the loading or transport process, data signals that are embodied in carrier waves (transmitted over telephone lines, network lines, wireless links, cables, and the like) communicate the code segments, including instructions, to the system. Such carrier waves are in the form of electrical, optical, acoustical, electromagnetic, or other types of signals.

While the invention has been disclosed with respect to a limited number of embodiments, those skilled in the art will appreciate numerous modifications and variations therefrom. It is intended that the appended claims cover such modifications and variations as fall within the true spirit and scope of the invention.

What is claimed is:

1. A method of performing a test, comprising:
performing a first test with a first test system;
performing a second test with a second test system:
in each of the first and second test systems, receiving plural parameters; and
in each of the first and second test systems, identifying a file name of a data file to use in each of the first and second tests based on the plural parameters.

2. The method of claim 1, further comprising performing at least another test with at least another test system using the data file.

3. The method of claim 1, further comprising, in each of the first and second test systems, accessing a storage system over a network to find a file name containing strings in each of the plural parameters.

4. The method of claim 3, wherein accessing the storage system comprises accessing the storage system to find a file name containing a concatenation of the strings.

5. The method of claim 1, wherein each of the tests is performed on a database, and wherein one of the parameters represents the database.

6. A method of performing a test, comprising:
receiving a first value;
receiving a second value representing a database to perform a test on; and
combining the first value and the second value to generate a file name of a test file to use in the test.

7. The method of claim 6, wherein receiving the test value comprises receiving a predetermined string, the predetermined string being part of the file name of the test file.

8. The method of claim 6, further comprising performing the test using a test module and invoking a routine, from the test module, to generate the file name of the test file.

9. The method of claim 8, further comprising executing the test module in a test system.

10. The method of claim 9, further comprising the test module performing a test on the database coupled over a network.

11. The method of claim 6, further comprising performing the test using a first test system, wherein the receiving and combining acts are performed in the first test system.

12. The method of claim 11, further comprising, in a second system:
receiving the first value;
receiving the second value representing the database;
combining the first value and the second value to generate the file name of the test file; and
performing another test on the database using the test file.

13. The method of claim 12, wherein the first test system performs a first type of test and the second test system performs a second type of test.

14. A test system comprising:
an interface to a network coupled to a storage unit containing a data file for use in a test;
a control unit;
a routine executable on the control unit to receive a first parameter and a second parameter and to combine the first and second parameters to form a string, the routine to identify a file name of the data file based on the string.

15. The test system of claim 14, further comprising a test module executable on the control unit to perform the test.

16. The test system of claim 15, wherein the routine is invocable by the test module.

17. The test system of claim 14, wherein the routine is executable to access the storage unit and to search file names on the storage unit for a file name containing the string.

18. The test system of claim 14, further comprising a test module is executable on the control unit to perform a test of a database coupled to the network, the second parameter representing the database.

19. The test system of claim 18, wherein the test module is executable to pass the first and second parameters to the routine.

20. The test system of claim 19, wherein the routine is executable to prompt a user for one or both of the first and second parameters if not passed by the test module.

21. The test system of claim 20, wherein the routine is executable to set a file name of a default data file if not received from the test module or the user.

22. An article comprising at least one storage medium containing instructions that when executed cause a system to:
combine a first parameter and a second parameter to form a string;
access a storage unit over a network, the storage unit containing plural data files; and
identify one of the data files based on the string to for using in a test procedure.

23. A method of performing a test, comprising:
receiving a first parameter containing a predetermined value;
receiving a second parameter representing a database to perform a test on;
concatenating the first parameter and the second parameter to generate a string that is at least a portion of a file name; and
searching a predetermined directory on a device to find a test file containing the string.

24. The method of claim 23, further comprising accessing the device over a network to search the predetermined directory.

25. The method of claim 23, further comprising:
prompting a user for a value of the first parameter; and
setting a default value for the first parameter if the first parameter value is not received from the user.

26. The method of claim 25, further comprising:
prompting the user for a value of the second parameter; and
setting a default value for the second parameter if the second parameter value is not received from the user.

27. A system comprising:
an interface to a network coupled to a storage unit containing a directory of data files;
a control unit;
a routine executable on the control unit to receive a first parameter and a second parameter and to concatenate the first and second parameters to form a string, the first parameter containing a predetermined value, and the second parameter representing a database to perform a test on,
the routine executable to search the directory to find a file name of one of the data files that contains the string and to set the one data file as the data file to use for the test; and
a test module executable on the control unit to perform the test.

28. A method of performing tests, comprising:
receiving a predetermined common parameter;
receiving a second parameter representing a database to perform a test on;
concatenating the common parameter and the second parameter to generate a string that is at least a portion of a file name; and
searching a predetermined directory on a device to find a test file containing the string,
wherein receiving the common parameter, receiving the second parameter, concatenating the common parameter and the second parameter, and searching the predetermined directory is performed in each of plural test systems.
